(19) United States
(12) Patent Application Publication
(10) Pub. No.: US 2025/0096188 A1
(43) Pub. Date: Mar. 20, 2025

(54) Die Bonding Apparatus, Mounting Method, and Method for Manufacturing Semiconductor Device

(71) Applicant: Fasford Technology Co., Ltd., Minami-Alps City (JP)

(72) Inventor: Keita YAMAMOTO, Minami Alps (JP)

(21) Appl. No.: 18/801,984

(22) Filed: Aug. 13, 2024

(30) Foreign Application Priority Data
Sep. 15, 2023 (JP) 2023-149681

(51) Int. Cl. H01L 23/00; H01J 37/32

(52) U.S. Cl. CPC H01L 24/74; H01J 37/32449; H01L 24/80; H01L 2224/74; H01L 2224/80009; H01L 2224/80895; H01L 2224/80896; H01L 2924/40

(57) ABSTRACT

An object of the disclosure is to provide a technique that enables surface activated bonding between a die and a substrate, and, a die bonding apparatus includes: a first bonding head that picks up a die; a first bonding stage that holds a substrate; and a plasma irradiator that irradiates, with plasma, the surface of the die picked up by the first bonding head and the surface of the substrate held by the first bonding stage.

### CLAIM OF PRIORITY

The present application claims priority from Japanese patent application JP 2023-149681 filed on Sep. 15, 2023, the content of which is hereby incorporated by reference into this application.

### BACKGROUND

The present disclosure relates to a die bonding apparatus, and can be applied to a flip-chip bonder performing surface activated bonding, for example.

The die bonding apparatus (semiconductor manufacturing apparatus, mounting apparatus) includes a flip-chip bonder that picks up a die separated from a wafer and having a bump on its surface, and flips the picked-up die over and bonds the die to a substrate with the surface of the die downward (facedown) (for example, Japanese Unexamined Patent Application Publication No. 2023-45346).

### SUMMARY

An object of the disclosure is to provide a technique that enables surface activated bonding between a die and a substrate. Other objects and novel features will be clarified from the description herein and the accompanying drawings.

A brief overview of typical features of the disclosure is as follows.

Specifically, a die bonding apparatus includes a first bonding head that picks up a die, a first bonding stage that holds a substrate, and a plasma irradiator that irradiates, with plasma, the surface of the die picked up by the first bonding head and the surface of the substrate held by the first bonding stage.

According to the disclosure, surface activated bonding can be performed.

### BRIEF DESCRIPTION OF THE DRAWINGS

FIG. 1 is a top diagram schematically showing a flip-chip bonder of an embodiment,

FIG. 2 is a schematic cross-sectional view of a major portion of a wafer supply unit shown in FIG. 1,

FIG. 3 is a schematic front view of the periphery of a pickup unit of the flip-chip bonder shown in FIG. 1,

FIG. 4 is a schematic side view of a temporary compression bonding part of a bonding unit of the flip-chip bonder shown in FIG. 1,

FIG. 5 is a schematic side view of a final compression bonding part of the bonding unit of the flip-chip bonder shown in FIG. 1,

FIG. 6 is a block diagram showing a schematic configuration of a control system of the flip-chip bonder shown in FIG. 1,

FIG. 7 is a flowchart showing a bonding method performed by the flip-chip bonder shown in FIG. 1,

FIG. 8 shows a configuration of a plasma irradiator shown in FIG. 1,

FIG. 9 illustrates a plasma irradiation method at a first bonding part,

FIG. 10 also illustrates the plasma irradiation method at the first bonding part,

FIG. 11 illustrates a plasma irradiation method in a first modification,

FIG. 12 also illustrates the plasma irradiation method in the first modification,

FIG. 13 illustrates a plasma irradiation method in a second modification,

FIG. 14 also illustrates the plasma irradiation method in the second modification,

FIGS. 15A and 15B illustrate a bonding step in a third modification, and

FIGS. 16A and 16B also illustrate the bonding step in the third modification.

### DESCRIPTION OF THE PREFERRED EMBODIMENTS

Hereinafter, one embodiment will be described with reference to drawings. However, the following description and drawings are each partially omitted or simplified as appropriate to clarify the description. Further, the same components are designated by the same reference numerals or signs, and repeated description thereof may be omitted. It should be noted that to make the description more clearly, the drawings may be schematically shown for the widths, thicknesses, shapes, and the like of the respective portions as compared with the actual form.

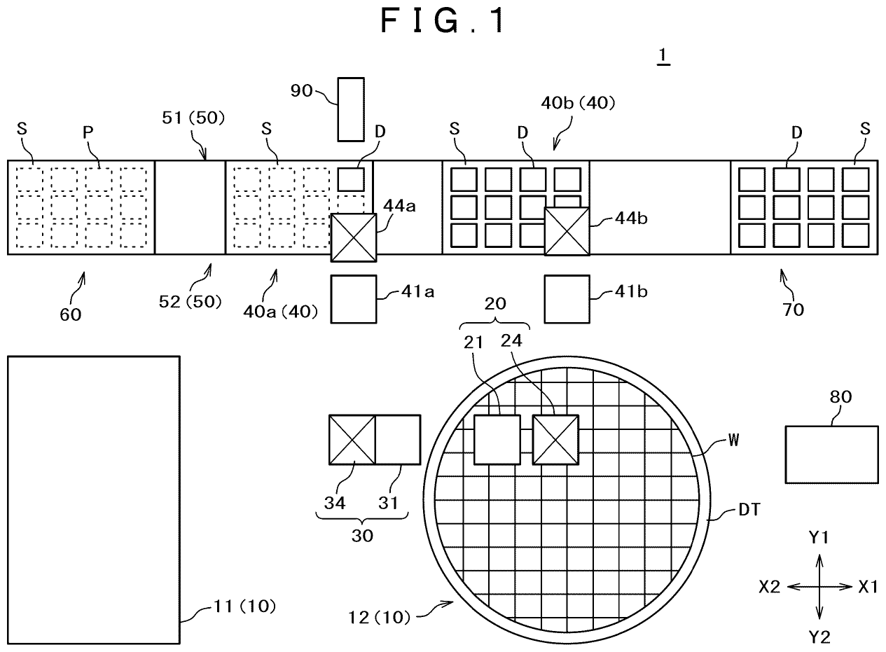

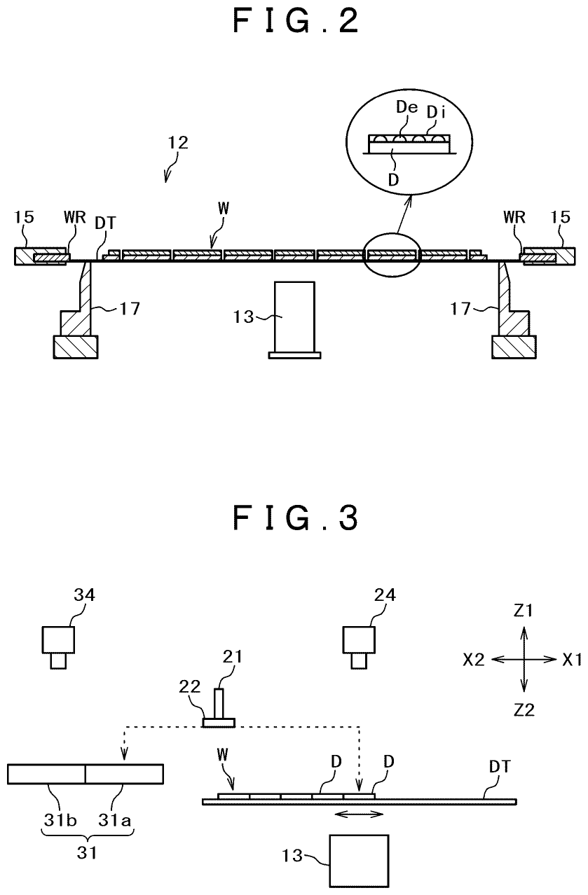

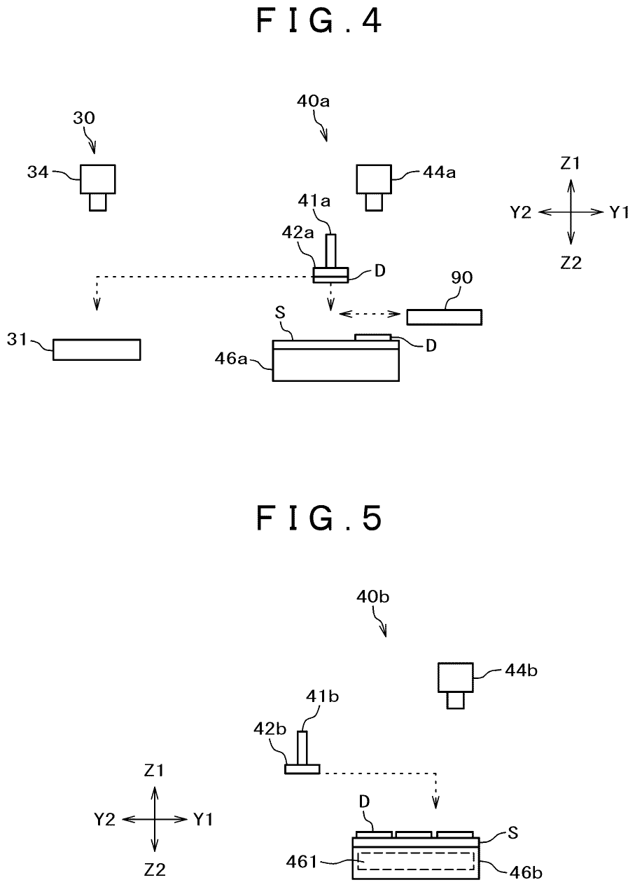

The configuration of a flip-chip bonder, which is one embodiment of a die bonding apparatus, is now described with reference to FIGS. 1 to 5. FIG. 1 is a schematic top view of an exemplary configuration of the flip-chip bonder of the embodiment. FIG. 2 is a schematic cross-sectional view of a major portion of a wafer supply unit shown in FIG. 1. FIG. 3 is a schematic front view of the periphery of a pickup unit of the flip-chip bonder shown in FIG. 1. FIG. 4 is a schematic side view of a temporary compression bonding part of a bonding unit of the flip-chip bonder shown in FIG. 1. FIG. 5 is a schematic side view of a final compression bonding part of the bonding unit of the flip-chip bonder shown in FIG. 1.

As shown in FIG. 1, the flip-chip bonder 1 broadly has a wafer supply unit 10, a pickup unit 20, an intermediate stage unit 30, a bonding unit 40, a transfer unit 50, a substrate supply unit 60, a substrate unloading unit 70, and a control unit (controller) 80. The Y2-Y1 direction is the longitudinal direction of the flip-chip bonder 1, the X2-X1 direction is the horizontal direction thereof, and the Z1-Z2 direction is the vertical direction thereof. The wafer supply unit 10 is located on the front side of the flip-chip bonder 1, and the bonding unit 40 is located on the rear side thereof.

The wafer supply unit 10 has a wafer cassette lifter 11, a wafer holding table 12, and a peeling unit 13.

The wafer cassette lifter 11 vertically moves a wafer cassette (not shown), storing a plurality of wafer rings WR, up to a wafer transfer height. A wafer correction chute (not shown) aligns a wafer ring WR supplied from the wafer cassette lifter 11. A wafer extractor (not shown) extracts the wafer ring WR from a wafer cassette and supplies it to the wafer holding table 12, or extracts the wafer ring WR from the wafer holding table 12 and stores it in the wafer cassette.

A wafer W is adhered (affixed) onto a dicing tape DT while being divided into a plurality of dies D. The dicing tape DT is held by the wafer ring WR. The wafer W is, for example, a semiconductor wafer or a glass wafer, and the die D as a workpiece is a semiconductor chip, a glass chip, or micro electro mechanical systems (MEMS).

As shown in FIG. 2, the wafer holding table 12 has an expansion ring 15 to hold the wafer ring WR, and a support ring 17 to position the dicing tape DT horizontally. The wafer holding table 12 moves in the X1-X2 and Y1-Y2 directions with an undepicted drive part to move the die D to be picked up to a position of the peeling unit 13. In addition, the wafer holding table 12 rotates the wafer ring WR within the XY plane with an undepicted drive part. The peeling unit 13 vertically moves with an undepicted drive part. The peeling unit 13 peels the die D from the dicing tape DT.

As shown in FIGS. 1 and 3, the pickup unit 20 has a pickup head 21 and a wafer recognition camera 24. The pickup head 21 has a collet 22 to hold by adsorption the peeled die D at its tip end. The pickup head 21 picks up the die D from the wafer supply unit 10 and places the die D on an intermediate stage 31 with the surface (front surface) of the die D, on which metal electrodes De are formed, facing up. The pickup head 21 moves in the Z1-Z2, X1-X2, and Y1-Y2 directions.

The wafer recognition camera 24 checks a pickup position of the die D to be picked up from the wafer W and performs surface inspection of the die D.

As shown in FIGS. 1 and 3, the intermediate stage unit 30 includes the intermediate stage 31 on which the die D is placed, and a stage recognition camera 34 for recognizing the die D on the intermediate stage 31. The intermediate stage 31 includes a flip stage 31a and a pickup stage 31b. The die D is placed face up on the flip stage 31a, and the flip stage 31a flips to place the die D face down on the pickup stage 31b. The placed die D is temporarily held on the pickup stage 31b.

As shown in FIG. 1, the bonding unit 40 includes a temporary compression bonding part 40a and a final compression bonding part 40b. As shown in FIG. 4, the temporary compression bonding part 40a has a temporary compression bonding head 41a as a first bonding head, a substrate recognition camera 44a, a temporary compression bonding stage 46a as a first bonding stage, and a plasma irradiator 90. The temporary compression bonding head 41a has a collet 42a that holds the die D by adsorption at its tip end, as with the pickup head 21. The temporary compression bonding head 41a moves in the Y1-Y2 direction. The substrate recognition camera 44a takes an image of a position recognition mark (not shown) on the substrate S and recognizes the bonding position. When the die D is placed on the substrate S, the temporary compression bonding stage 46a rises and supports the substrate S from below. The temporary compression bonding stage 46a has a suction port (not shown) for vacuum adsorption of the substrate S and thus can fix the substrate S. According to such a configuration, the temporary compression bonding head 41a picks up the die D from the intermediate stage 31, and bonds the die D onto the substrate S, which has been transferred, based on the imaging data of the substrate recognition camera 44a.

As shown in FIG. 5, the final compression bonding part 40b has a final compression bonding head 41b as a second bonding head, a substrate recognition camera 44b, and a final compression bonding stage 46b as a second bonding stage. The final compression bonding head 41b has a collet 42b that presses the die D against the substrate S. The final compression bonding head 41b moves in the Y1-Y2 direction. When the die D is placed on the substrate S, the final compression bonding stage 46b rises and supports the substrate S from below. The final compression bonding stage 46b has a suction port (not shown) for vacuum adsorption of the substrate S and thus can fix the substrate S. The final compression bonding stage 46b heats the substrate S with a heating unit 461. According to such a configuration, the final compression bonding head 41b finally bonds by compression the die D, which has been temporarily bonded to the substrate S, to the substrate S. A load or load application time of the final compression bonding head 41b for final compression bonding is greater than that of the temporary compression bonding head 41a for temporary compression bonding. To check a bonding state of the die D, the substrate recognition camera 44b photographs the die D and the substrate S.

As shown in FIG. 1, the transfer unit 50 has transfer lanes 51 and 52 to move the substrate S in the X1-X2 direction. The transfer lanes 51 and 52 are provided in parallel with each other. According to such a configuration, the transfer unit 50 extracts the substrate S from the substrate supply unit 60, moves it along the transfer lanes 51, 52 to the substrate unloading unit 70 via the temporary compression bonding stage 46a and the final compression bonding stage 46b, and passes the substrate S to the substrate unloading unit 70.

The substrate supply unit 60 extracts the substrate S, which has been loaded while being stored in a transfer jig, from the transfer jig, and supplies it to the transfer unit 50. The substrate unloading unit 70 stores the substrate S, which has been transferred by the transfer unit 50, in a transfer jig.

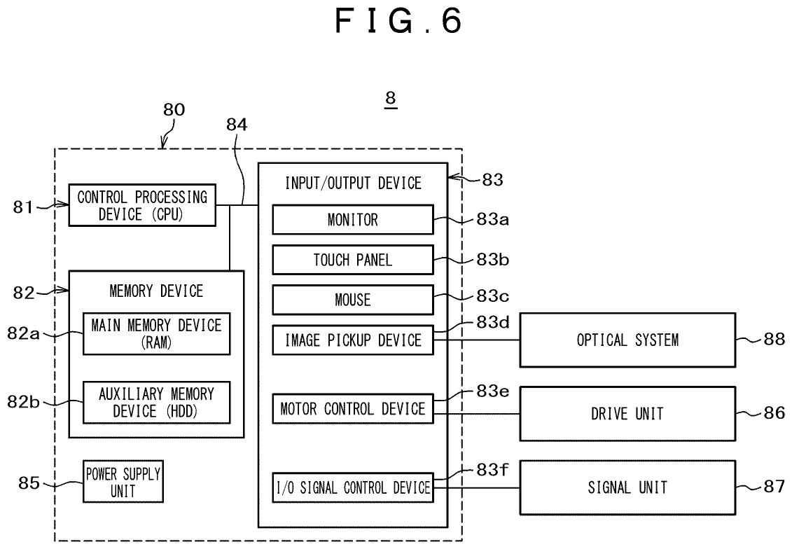

A control system of the flip-chip bonder 10 is now described with reference to FIG. 6. FIG. 6 is a block diagram schematically showing a configuration of the control system of the flip-chip bonder shown in FIG. 1.

A control system 8 includes the control unit (controller) 80, a drive unit 86, a signal unit 87, and an optical system 88. The control unit 80 is configured as a computer broadly including a control processing device 81 mainly including a central processing unit (CPU), a memory device 82, an input/output device 83, a bus line 84, and a power supply unit 85. The memory device 82 includes a main memory device 82a and an auxiliary memory device 82b. The main memory device 82a includes a random access memory (RAM) that stores processing programs and the like. The auxiliary memory device 82b includes a hard disk drive (HDD) or a solid state drive (SSD) that stores control data necessary for control, image data, and the like. The control unit 80 can be connected to an external storage device.

The input/output device 83 includes a monitor 83a to display a device state of the flip-chip bonder 1, information, etc., a touch panel 83b to input operator instructions, a mouse 83c to operate the monitor 83a, and an image pickup device 83d to capture image data from the optical system 88. The input/output device 83 further includes a motor control device 83e and an I/O signal control device 83f. The motor control device 83e controls a drive part of an XY table (not shown) of the wafer supply unit 10, a drive part of a pickup head table, a drive part of a bonding head table, and a drive part of the peeling unit 13, and the like. The I/O signal control device 83f acquires a signal from the signal unit 87 and controls the signal unit 87. The signal unit 87 includes various sensors, and a switch, a volume, etc. for controlling brightness of a lighting device or the like. The optical system 88 includes the wafer recognition camera 24, the stage recognition camera 34, and the substrate recognition cameras 44a and 44b. The wafer recognition camera 24, the stage recognition camera 34, and the substrate recognition cameras 44a and 44b each convert light intensity or a color into numerical values. The control processing device 81 acquires necessary data via the bus line 84, performs calculations, controls the pickup head 21 and the like, and transmits information to the monitor 83a or the like.

The control unit 80 stores, in the memory device 82, image data captured via the image pickup device 83d by the wafer recognition camera 24, the stage recognition camera 34, and the substrate recognition cameras 44a and 44b. The die D and the substrate S are subjected to positioning and visual inspection using the control processing device 81 by software programmed based on the stored image data. The drive unit 86 is operated by software via the motor control device 83e based on the positions of the die D and the substrate S calculated by the control processing device 81. The die on the wafer is positioned through such a process, and the pickup head table and the bonding head table are operated to bond the die D onto the substrate S.

The control unit 80 can be configured by installing on a computer the above program stored in the external storage device. The external storage device includes, for example, HDD, a universal serial bus (USB) memory, SSD, etc. The auxiliary memory device 82b and the external storage device are each configured as a computer-readable recording medium. Hereinafter, these recording media may be collectively referred to simply as recording media. When the term “recording media” is used herein, it may include only the auxiliary memory device 82b, only the external storage device, or both. A program or data may be provided to a computer, or may be provided from the computer to an external device without the external storage device but with a communication unit such as the Internet or a dedicated line.

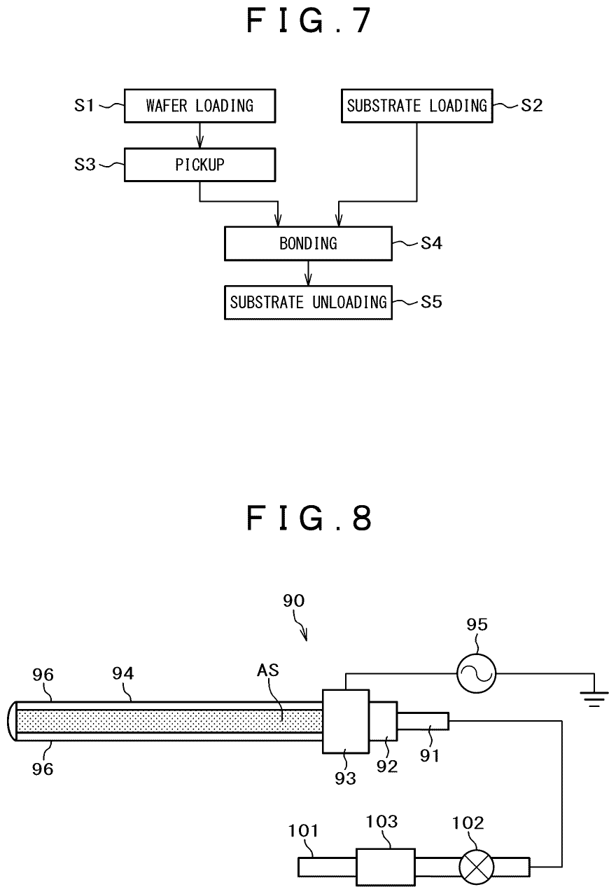

Some of manufacturing steps of a semiconductor device (manufacturing method of a semiconductor device) using the flip-chip bonder 1 is now described with reference to FIG. 7. FIG. 7 is a flowchart showing the manufacturing method of the semiconductor device using the flip-chip bonder shown in FIG. 1. In the following description, operation of each part configuring the flip-chip bonder 1 is controlled by the control unit 80.

(Wafer loading step: Step S1)

A wafer cassette (not shown) storing wafer rings WR is loaded into the wafer cassette lifter 11. The dicing tape DT, to which dies D separated from the wafer W are affixed, is attached to the wafer ring WR. The wafer supply unit 10 extracts a wafer ring WR from the wafer cassette filled with the wafer rings WR, and loads the wafer ring WR onto the wafer holding table 12.

The wafer W is, for example, a semiconductor wafer, and the die D as a workpiece is a semiconductor chip. The surface of the die D faces upward on the dicing tape DT, and as shown in FIG. 2, for example, an insulating film Di is provided on the surface of the die D while having openings in each of which a metal electrode De is provided.

### (Substrate Loading Step: Step S2)

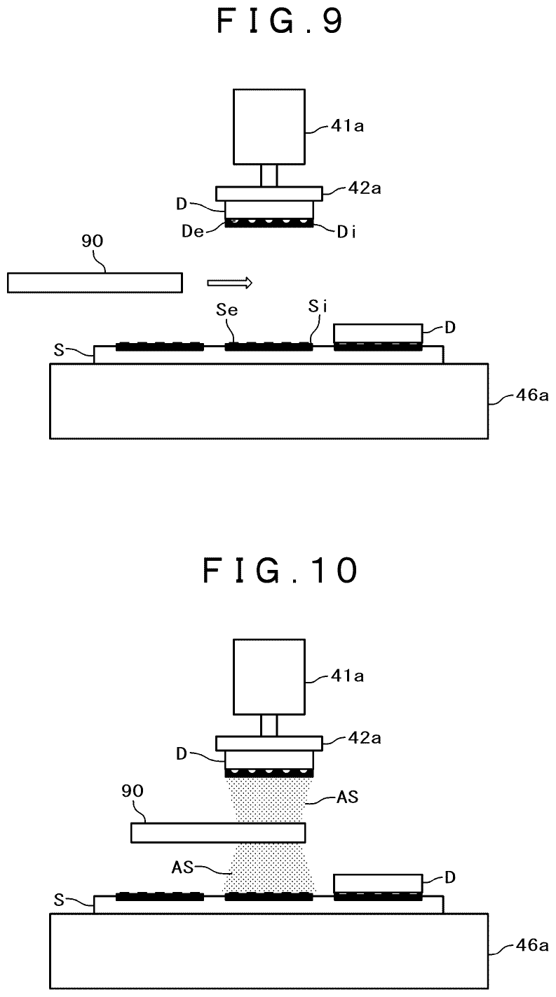

The transfer jig storing the substrate S is loaded into the substrate supply unit 60. The substrate supply unit 60 extracts the substrate S from the transfer jig. The extracted substrate S is loaded into the bonding unit 40 via the transfer unit 50. An insulating film Si is provided on the surface of the substrate S, and a metal electrode Se is provided in each of openings of the insulating film Si (see FIG. 9).

### (Pickup Step: Step S3)

After step S1, the wafer holding table 12 moves so that a desired die D can be picked up from the dicing tape DT. The wafer recognition camera 24 photographs the Die D. Positioning and surface inspection of the die D are performed based on the image data acquired by the photographing. Through image processing of the image data, the amount of deviation (in the X, Y, and 0 directions) of the die D on the wafer holding table 12 from the die position reference point of the flip-chip bonder is calculated for positioning. The die position reference point is in advance held at a predetermined position on the wafer holding table 12 as initial setting of the bonder. The surface inspection of the die D is performed through image processing of the image data.

The peeling unit 13 moves upward so that the top surface of the peeling unit 13 comes into contact with the back surface of the dicing tape DT. The peeling unit 13 then adsorbs the dicing tape DT. The pickup head 21 descends while evacuating the collet 22, lands on the die D to be peeled, and adsorbs the die D. The pickup head 21 lifts the collet 22 and peels the die D from the dicing tape DT. As a result, the die D is picked up by the pickup head 21.

The pickup head 21 moves along the X1-X2 direction from the pickup position to above the flip stage 31a of the intermediate stage 31. The pickup head 21 descends and places the die D, held on the collet 22, on the flip stage 31a. The flip stage 31a rotates 180 degrees so that the surface (front surface) of the die D, on which the metal electrodes De are formed, is flipped to face downward, and places the die D on the pickup stage 31b.

The stage recognition camera 34 photographs the die D on the pickup stage 31b. Positioning and surface inspection of the die D are performed based on the image data acquired by the photographing. Through image processing of the image data, the amount of deviation (in the X, Y, and 0 directions) of the die D on the pickup stage 31b from the die position reference point of the flip-chip bonder is calculated for positioning. The die position reference point is in advance held at a predetermined position on the pickup stage 31b as initial setting of the bonder. The surface inspection of the die D is performed through image processing of the image data.

After transferring the die D to the intermediate stage 31, the pickup head 21 is returned to the wafer holding table 12. According to the above procedure, a subsequent die D is peeled from the dicing tape DT, and then the dies D are peeled one by one from the dicing tape DT according to the same procedure.

### (Bonding Step: Step S4)

The transfer unit 50 transfers the substrate S to the temporary compression bonding stage 46a. The substrate recognition camera 44a photographs the substrate S placed on the temporary compression bonding stage 46a. Positioning and surface inspection of the substrate S are performed based on the image data acquired by the photographing. Through image processing of the image data, the amount of deviation (in the X, Y, and 0 directions) of the substrate S from the substrate position reference point of the flip-chip bonder 1 is calculated. The substrate position reference point is in advance held at a predetermined position of the bonding unit 40 as initial setting of the bonder. The surface inspection of the substrate S is also performed through image processing of the image data.

The temporary compression bonding head 41a, the adsorption position of which is corrected based on the amount of deviation of the die D on the intermediate stage 31 calculated in step S3, descends and adsorbs the die D with the collet 42a. The temporary compression bonding head 41a rises and picks up the die D from the intermediate stage 31. The temporary compression bonding head 41a moves from above the intermediate stage 31 to above the substrate S while holding the die D with the collet 42a.

The plasma irradiator 90 moves to a position below the temporary compression bonding head 41a and above the substrate S. The plasma irradiator 90 irradiates the surfaces on the die D and surfaces at predetermined locations on the substrate S with plasma to activate the respective surfaces (plasma processing). Subsequently, the plasma irradiator 90 is retracted.

The temporary compression bonding head 41a descends and temporarily bonds by compression the die D, held by the collet 42a, onto a predetermined location on the substrate S. As a result, the insulating film Di on the surface of the die D is bonded to the insulating film Si on the surface of the substrate S.

The substrate recognition camera 44a photographs the die D bonded to the substrate S. Inspections on whether the die D has been bonded at a desired position (inspection of relative positions of the die D and the substrate S) and the like are performed based on the image data acquired by the photographing.

After temporarily bonding by compression the die D to the substrate S, the temporary compression bonding head 41a is returned to the intermediate stage 31. According to the above procedure, a subsequent die D is picked up from the intermediate stage 31 and temporarily bonded by compression to the substrate S. Such a process is repeated until the dies D are temporarily bonded by compression on the entire substrate S.

The transfer unit 50 transfers the substrate S onto the final compression bonding stage 46b. The heating unit 461 heats the substrate S on the final compression bonding stage 46b. The final compression bonding head 41b moves from its retracted position to above the die D temporarily bonded by compression to the substrate S. The final compression bonding head 41b descends and finally bonds by compression the die D to the substrate S with the collet 42b. Through such heating and pressurization, the metal electrodes De on the surface of the die D are bonded to the metal electrodes Se on the surface of the substrate S. The substrate recognition camera 44b photographs the die D and the substrate S. Surface inspection (check of compression-bonded state) is performed based on the image data acquired by the photographing.

### (Substrate Unloading Step: Step S5)

The substrate S with the die D bonded thereto is transferred to the substrate unloading unit 70. The substrate unloading unit 70 stores the substrate S in the transfer jig. The transfer jig storing the substrate S is unloaded from the flip-chip bonder 1.

The plasma irradiator 90 is now described with reference to FIG. 8. FIG. 8 shows a configuration of the plasma irradiator shown in FIG. 1.

The plasma irradiator 90 performs remote atmospheric-pressure plasma processing (surface activation treatment) at room temperature. The plasma irradiator 90 includes a gas inlet 91, a gas inlet nozzle 92, a plasma generator 93, and a nozzle 94, where the plasma generator 93 is connected to a high-frequency power supply 95. In this configuration, processing gas is introduced through the gas inlet 91, and flows toward the nozzle 94 through the inside of the gas inlet nozzle 92. During the flow, high-frequency power is applied in the plasma generator 93 by the high frequency power supply 95, and thus the passing processing gas is activated, generating activated species AS of the processing gas. The activated species AS generated inside the plasma generator 93 is transferred to the inside of the nozzle 94 by the gas flow and is ejected from gas supply holes 96 provided at the nozzle 94. Some of the gas supply holes 96 are provided on a side facing the die D (upper side), and the rest thereof are on a side facing the substrate S (lower side). The gas inlet 91 is connected to a supply source of the processing gas via piping 101, a valve 102, and a flow controller 103. The piping 101, the valve 102, and the flow controller 103 may be included in the plasma irradiator 90.

The gas introduction nozzle 92 is made of a material having low electrical conductivity, commonly referred to as an insulator, such as glass, quartz glass, or alumina. However, a portion of the gas introduction nozzle 92, which is not in contact with the electrode in the plasma generator 93, may be partially made of a metal, generally referred to as a conductor, such as stainless steel or aluminum (Al). The gas introduction nozzle 92 has a tubular central portion for introducing gas with a circular or rectangular cross-section.

For example, nitrogen (N) gas can be used as the processing gas. Nitrogen plasma is thus generated by applying high-frequency power in the plasma generator 93. The activated species AS released by the plasma is applied onto the surfaces of the die D and the substrate S, leading to surface activation treatment. In the surface activation treatment, energy is applied to interatomic bonds of a material to break the bonds, resulting in an unstable state and in higher chemical reactivity. The processing gas may include rare gases such as argon (Ar) and helium (He) without being limited to nitrogen.

The surface activation treatment method for the die D and the substrate S by the plasma irradiator 90 is now described with reference to FIGS. 9 and 10. FIGS. 9 and 10 illustrate a plasma irradiation method at a first bonding part.

As shown in FIG. 9, the temporary compression bonding head 41a picks up the die D from the intermediate stage 31 and transfers it to above a placed position of the substrate S. For example, the die D has, on its surface, the metal electrode De made of copper (Cu) or gold (Au) and the insulating film Di made of polyimide or the like. For example, the substrate S also has, on its surface, the metal electrode of Cu or Au and the insulating film of polyimide or the like.

As shown in FIG. 10, the plasma irradiator 90 moves to between the die D and the substrate S. The plasma irradiator 90 irradiates with plasma the surface of the substrate S and the surface of the die D at the same time. More specifically, the plasma irradiator 90 emits plasma from multiple gas supply holes 96 provided at the top and bottom of the nozzle 94. Plasma irradiation time is, for example, preferably 5 sec or less, and more preferably about 1 sec. As a result, the insulating film Di of the die D and the insulating film Si of the substrate S are activated. Subsequently, the temporary compression bonding head 41a descends, places the die D on the substrate S, and presses the die D to the substrate S. As a result, the insulating film Di of the die D is bonded to the insulating film Si of the substrate S.

According to this embodiment, since plasma is applied immediately before bonding of the die D to the substrate S, the bonding can be performed without contact with an activated bonding surface. In addition, each bonding surface is less likely to be inactive before bonding. This increases bonding strength between the die D and the substrate S. Furthermore, since bonding is performed while the bonding surface is activated, bonding defects can be reduced.

According to this embodiment, surface activated bonding can be performed, allowing hybrid bonding. As a result, the degree of integration can be increased because hybrid bonding allows mounting positions to be spaced at narrower pitches. The hybrid bonding also enables mounting in chiplet technology. In the chiplet technology, components of an integrated circuit, including CPU, GPU, and an accelerator, are divided into multiple chips for each function, and the chips are manufactured using the optimal processes, and then combined and packaged into one chip. The chiplet technology employs, for example, a silicon interposer having, on its surface, a redistribution layer (RDL) including a Cu or Au electrode and an insulating film of polyimide or the like.

According to this embodiment, plasma processing is performed in the atmosphere, which eliminates the need for a vacuum chamber or the like. This makes it possible to suppress an increase in size of the flip chip bonder. Such a flip chip bonder can be achieved by simply adding the plasma irradiator to an existing flip chip bonder, and thus can be achieved by modifying the existing flip chip bonder.

### Modifications

Some typical modifications of the embodiment are exemplified below. In the following description of the modifications, the same reference numeral as in the embodiment may be used for a portion having the same configuration and function as that described in the embodiment. For description of such a portion, the description in the embodiment may be used as appropriate within the scope without any technical contradiction. Part of the embodiment and all or some of a plurality of modifications may be applied in combination as appropriate within the scope without any technical contradiction.

### First Modification

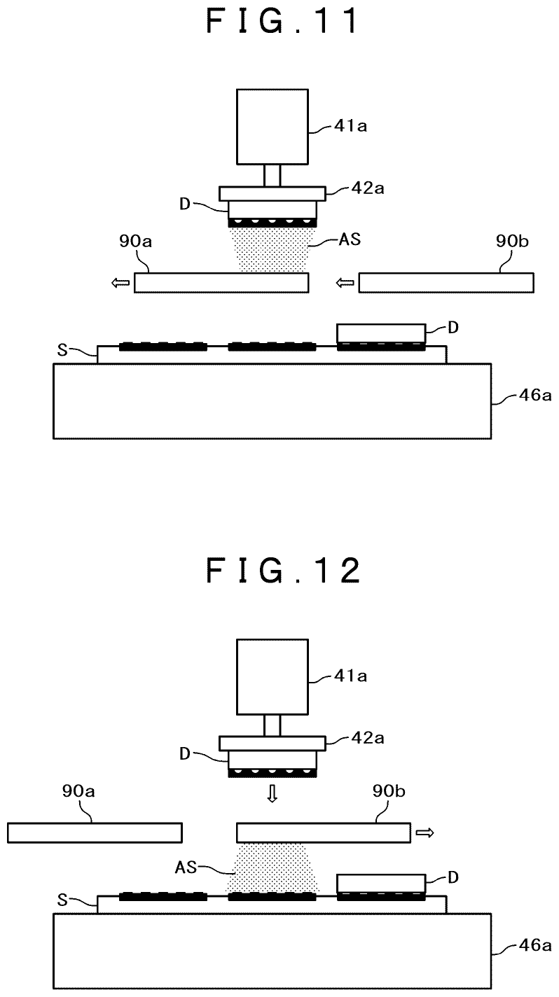

A plasma irradiation method in a first modification is now described with reference to FIGS. 11 and 12. FIGS. 11 and 12 illustrate the plasma irradiation method in the first modification.

Although the embodiment has been described with an example where plasma is applied to the die D and the substrate S at the same timing by one plasma irradiator 90, plasma may be applied to the die D and the substrate S at different timings by two plasma irradiators.

For example, the temporary compression bonding part 40a includes a first plasma irradiator 90a and a second plasma irradiator 90b. The first plasma irradiator 90a has gas supply holes 96 only on the side facing the die D (upper side). The second plasma irradiator 90b has gas supply holes 96 only on the side facing the substrate S (lower side).

First, as shown in FIG. 11, the first plasma irradiator 90a moves from its retracted position to below the die D. The first plasma irradiator 90a then irradiates the surface of the die D with plasma.

Subsequently, as shown in FIG. 12, the first plasma irradiator 90a moves to the retracted position, and the second plasma irradiator 90b moves to between the die D and the substrate S. The second plasma irradiator 90b then irradiates the surface of the substrate S with plasma. Subsequently, the second plasma irradiator 90b moves to its retracted position.

### Second Modification

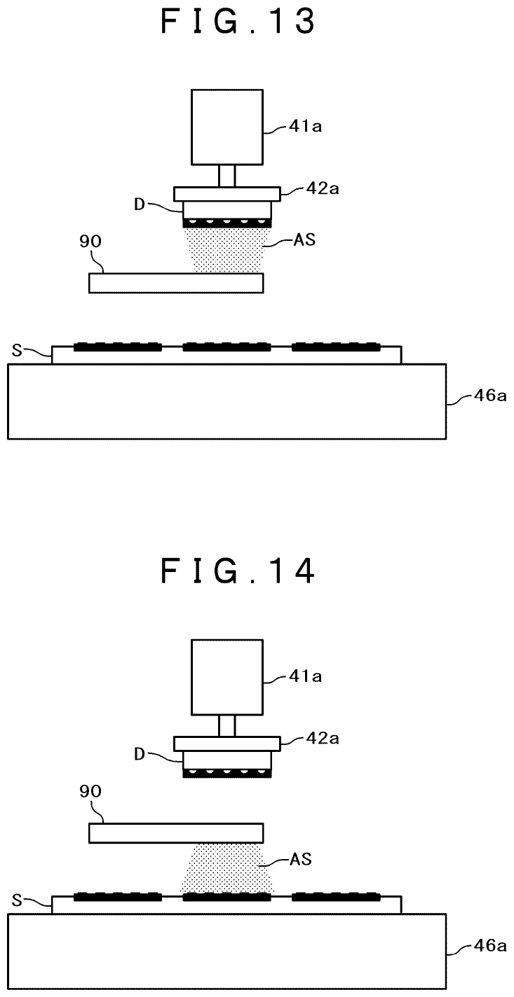

A plasma irradiation method in a second modification is now described with reference to FIGS. 13 and 14. FIGS. 13 and 14 illustrate the plasma irradiation method in the second modification.

Although the embodiment has been described with the example where plasma is applied to the die D and the substrate S at the same timing by one plasma irradiator 90, plasma may be applied to the die D and the substrate S at different timings by one plasma irradiator.

As in the embodiment, the plasma irradiator 90 has gas supply holes 96 on the side facing the die D (upper side) and on the side facing the substrate S (lower side). The upper gas supply holes 96 and the lower gas supply holes 96 are configured to be able to perform plasma irradiation separately. Either of the surface of die D and the surface of substrate S may be irradiated with plasma first.

First, as shown in FIG. 13, the plasma irradiator 90 moves from its retracted position to between the die D and the substrate S. The plasma irradiator 90 then irradiates the surface of the die D with plasma.

Subsequently, as shown in FIG. 14, the plasma irradiator 90 irradiates the surface of the substrate S with plasma. Subsequently, the plasma irradiator 90 moves to the retracted position.

The plasma irradiator 90 may have the gas supply holes 96 on the side facing the die D (upper side) or the side facing the substrate S (lower side), i.e., on only one side. In addition, the direction (irradiation direction) of the gas supply holes 96 can be changed by flipping or rotating the plasma irradiator 90. As a result, as shown in FIGS. 13 and 14, it is possible to irradiate the die D and the substrate S with plasma at different timings by one plasma irradiator.

### Third Modification

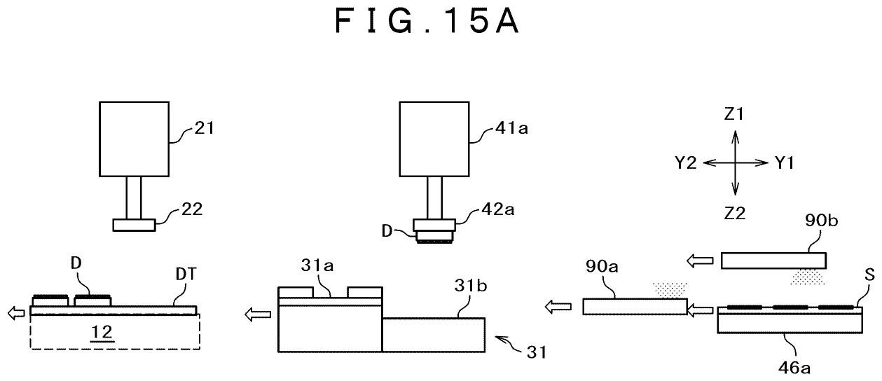

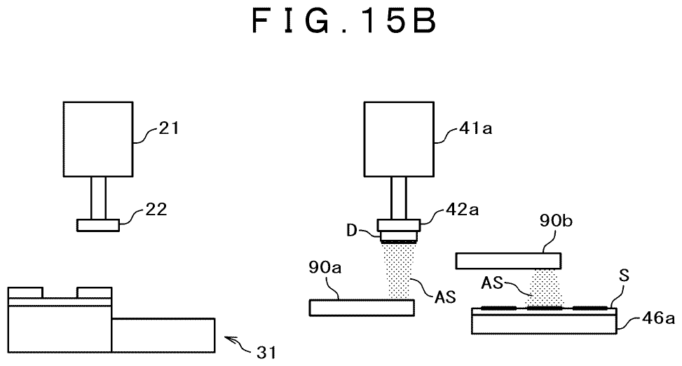

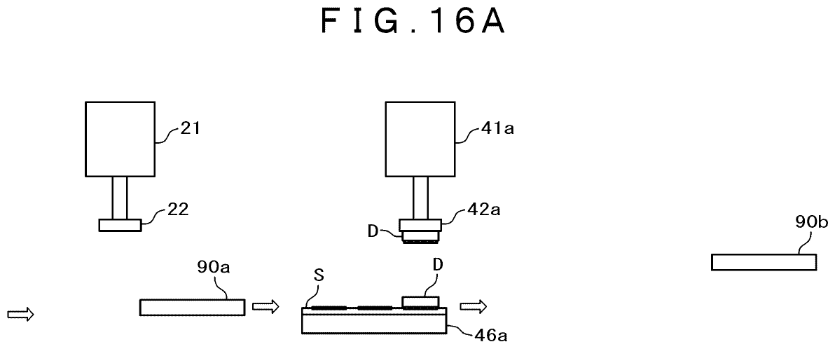

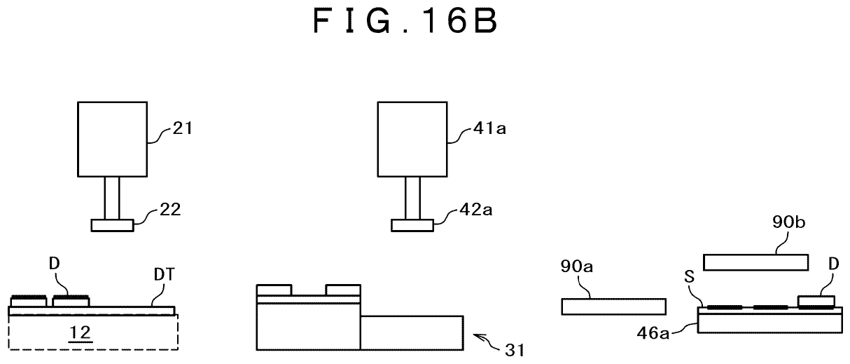

The bonding step in a third modification is now described with reference to FIGS. 15A and 15B and FIGS. 16A and 16B. FIG. 15A shows a position (initial position, pickup position) of each element when a first bonding head picks up a die from the intermediate stage. FIG. 15B shows a position of each element (plasma irradiation position) when the plasma irradiator irradiates the die and the substrate with plasma. FIG. 16A shows a position (bonding position) of each element when the first bonding head bonds the die to the substrate. FIG. 16B shows a state where each element has returned to its initial position.

The embodiment has been described with an example where the temporary compression bonding head 41a is moved horizontally and vertically to pick up the die D or place the die D on the substrate S. However, the disclosure is not limited thereto. For example, it is acceptable that the temporary compression bonding head 41a performs only vertical movement after moving to above the intermediate stage 31, while the wafer holding table 12, the intermediate stage 31, the temporary compression bonding stage 46a, and the plasma irradiator 90 are moved.

As shown in FIG. 15A, the wafer holding table 12, the intermediate stage 31, the temporary compression bonding stage 46a, the first plasma irradiator 90a, and the second plasma irradiator 90b are each disposed along the Y1-Y2 direction and movable along the Y1-Y2 direction.

After the temporary compression bonding head 41a picks up the die D, as shown by the arrow in FIG. 15A, the wafer holding table 12, the intermediate stage 31, the temporary compression bonding stage 46a, the first plasma irradiator 90a, and the second plasma irradiator 90b move in the Y2 direction. The wafer holding table 12, the intermediate stage 31, the temporary compression bonding stage 46a, the first plasma irradiator 90a, and the second plasma irradiator 90b are thus disposed at the positions shown in FIG. 15B. In this state, the first plasma irradiator 90a and the second plasma irradiator 90b irradiate the die D and the substrate S, respectively, with plasma.

After the plasma irradiation, the wafer holding table 12, the intermediate stage 31, the temporary compression bonding stage 46a, and the first plasma irradiator 90a move in the Y2 direction. The second plasma irradiator 90b moves in the Y1 direction. The temporary compression bonding stage 46a, the first plasma irradiator 90a, and the second plasma irradiator 90b are thus disposed at positions as shown in FIG. 16A. In this state, the temporary compression bonding head 41a bonds the die D to the substrate S.

After the bonding, the wafer holding table 12, the intermediate stage 31, the temporary compression bonding stage 46a, and the first plasma irradiator 90a move in the Y1 direction. The wafer holding table 12, the intermediate stage 31, the temporary compression bonding stage 46a, the first plasma irradiator 90a, and the second plasma irradiator 90b are thus disposed at positions as shown in FIG. 16B.

Although the disclosure made by the present disclosers has been specifically described based on the embodiment and the modifications, it is obvious that the disclosure is not limited thereto and can be modified in various ways.

Although the embodiment has been described with an example where the final compression bonding part 40b is provided in the bonding unit 40, the final compression bonding part 40b may be provided outside the flip chip bonder 1.

Although the embodiment has been described with an example where the flip mechanism is provided in the intermediate stage, the flip mechanism may be provided in a pickup flip head so that the die is received from the pickup flip head with a transfer head and placed on the intermediate stage.

Although the embodiment has been described with an example where the intermediate stage unit and the bonding unit are each provided singly, the respective units may be provided plurally.

Although the embodiment has been described with an example where the bonding head is provided singly, a plurality of bonding heads may be provided.

What is claimed is:

1. A die bonding apparatus, comprising:
a first bonding head to pick up a die;
a first bonding stage to hold a substrate; and
a plasma irradiator that irradiates with plasma a surface of the die picked up by the first bonding head and a surface of the substrate held by the first bonding stage.

2. The die bonding apparatus according to claim 1,
wherein the plasma irradiator includes gas supply holes to emit plasma to the upper side and gas supply holes to emit plasma to the lower side.

3. The die bonding apparatus according to claim 2,
further comprising a control unit configured to perform plasma irradiation to the upper side and plasma irradiation to the lower side at the same time by the plasma irradiator.

4. The die bonding apparatus according to claim 2,
further comprising a control unit configured to perform plasma irradiation to the upper side and plasma irradiation to the lower side at different timings by the plasma irradiator.

5. The die bonding apparatus according to claim 1,
wherein the plasma irradiator includes gas supply holes to emit plasma in one direction, and
the die bonding apparatus further includes a control unit configured to direct the gas supply holes to the upper side and emit plasma, and subsequently direct the gas supply holes to the lower side and emit plasma.

6. The die bonding apparatus according to claim 1,
wherein the plasma irradiator includes a first plasma irradiator having gas supply holes to emit plasma to the upper side, and a second plasma irradiator having gas supply holes to emit plasma to the lower side.

7. The die bonding apparatus according to claim 6,
further comprising a control unit configured to perform plasma irradiation to the upper side by the first plasma irradiator and plasma irradiation to the lower side by the second plasma irradiator at the same time.

8. The die bonding apparatus according to claim 6,
further comprising a control unit configured to perform plasma irradiation to the upper side by the first plasma irradiator and plasma irradiation to the lower side by the second plasma irradiator at different timings.

9. The die bonding apparatus according to claim 1,
further comprising a second bonding head to pressurize the die placed on the substrate; and
a second bonding stage having a heating unit to heat the substrate on which the die is placed.

10. A mounting method, comprising the steps of:
picking up a workpiece;
holding a substrate;
irradiating with plasma a surface of the picked-up workpiece and a surface of the held substrate; and
bonding the workpiece irradiated with plasma to the substrate irradiated with plasma.

11. A method for manufacturing a semiconductor device, the method comprising the mounting method according to claim 10.
